(19) United States
(12) Patent Application Publication
(10) Pub. No.: US 2009/0135868 A1
(43) Pub. Date: May 28, 2009

(54) Optical transmitter able to resume APC operation automatically

(76) Inventor: Hiroto Ishibashi, Yokohama-shi (JP)

Correspondence Address: Michael A. Makuch, Esq.;Smith, Gambrell & Russell, LLP, Suite 800, 1850 M Street, NW, Washington, DC, 20036, US

(21) Appl. No.: 12/289,345

(22) Filed: Oct. 24, 2008

(30) Foreign Application Priority Data
Oct. 30, 2007 (JP) 2007-282052

(51) Int. Cl. H01S 5/02

(52) U.S. Cl. 372/38.02

(57) ABSTRACT

An optical transmitter is disclosed that provides a function to resume the APC operation automatically when the failure of the APC operation is due to the thermal runaway of the device in the APC loop. The controller included in the transmitter always monitors the bias current supplied to the LD, and the optical output from the LD. When the bias current exceeds a threshold, the controller decides whether the abnormal is due to the temporary thermal runaway or the fatal failure of the device within the APC loop, and begins to sense the ambient temperature of the LD for appropriate resuming after the thermal runaway is cleared.

### BACKGROUND OF THE INVENTION

1. Field of the Invention

The present invention relates to an optical transmitter, in particular, the invention relates to an optical transmitter applicable on an optical communication and having a function to protect a light-emitting semiconductor device from the breakdown.

2. Related Prior Arts

An optical transmitter with a function of the automatic power control (hereafter denoted as APC) has been well known in the optical communication. The APC stabilize the average power and the extinction ratio of the optical output emitted from the transmitter. Specifically, the APC monitors the optical output from the light-emitting device such as a semiconductor laser diode (hereafter denoted as LD) with a light-receiving device, typically a semiconductorphotodiode (hereafter denoted as PD), and adjusts a driving current supplied to the LD so as to maintain the average power and the extinction ratio.

The APC may sometimes provide other functions to raise an alarm when the driving current to the LD extraordinarily increases and to cease operating of the LD when a temperature of the LD shows an abnormality.

Various reasons are considered for the abnormality of the APC operation, one of which is a breakdown of at least one device within the APC feedback loop, which results in an excess current being provided to the LD, and the other of which is the increase of the driving current due to the degradation of the slope efficiency of the LD by an increase of the ambient and operating temperature of the LD. The latter reason is often called as the thermal runaway of the LD. The conventional APC stops the operation of the LD by monitoring the abnormality if the driving current supplied to the LD.

In a conventional transmitter, a procedure to recover the APC loop once shutdown was carried out to provide an external command from the outside of the transmitter, which took a considerable time. One reason why the recover took a time was that the conventional transmitter could not explicitly distinguish the former reason from the latter. Therefore, even the ambient temperature became an ordinary status; the transmitter could not begin the APC operation until the transmitter received the external command.

### SUMMARY OF THE INVENTION

One aspect of the invention relates to a configuration of an optical transmitter that comprises an APC loop, a temperature sensor and a controller. The APC loop includes an LD, a laser driver, a PD and an APC unit. The laser driver supplies a driving current to the LD. The LD emits an optical output responding to the driving current. The PD monitors the optical output. The APC unit controls the laser driver based on the optical output monitored by the PD so as to maintain an average power and an extinction ratio of the optical output. The temperature sensor senses an ambient temperature of the LD. The controller monitors the driving current, the optical output and the ambient temperature.

A feature of the optical transmitter according to the present invention is that the controller stops the APC loop when the driving current exceeds the first threshold and resumes the APC loop when the optical output at an instant immediately before the stop of the APC loop exceeds the second threshold and the ambient temperature becomes less than a third threshold.

Because the optical output at the instant immediate before the stop of the APC loop exceeds the second threshold, the abnormal increase of the driving current is due to an thermal runaway of at least one device including within the APC loop. Accordingly, the transmitter may automatically resume the APC loop after the ambient temperature becomes less than a third threshold, which means that the thermal runaway of the device becomes clear.

When the abnormal increase of the driving current is due to the fatal failure of the device including within the APC loop, which is reflected in a state that the optical output at the instant immediate before the stop of the APC loop is substantially zero, the APC loop may be resumed by an external command supplied from the outside of the transmitter

### BRIEF DESCRIPTION OF DRAWINGS

FIG. 1 is a block diagram of an optical transmitter according to an embodiment of the present invention; and

FIG. 2 is a flow chart explaining an algorithm to stop and to resume the optical output from the optical transmitter according to an embodiment of the present invention.

### DESCRIPTION OF PREFERRED EMBODIMENTS

Next, embodiments of an optical transmitter and a method to control the transmitter according to the present invention will be described as referring to accompanying drawings.

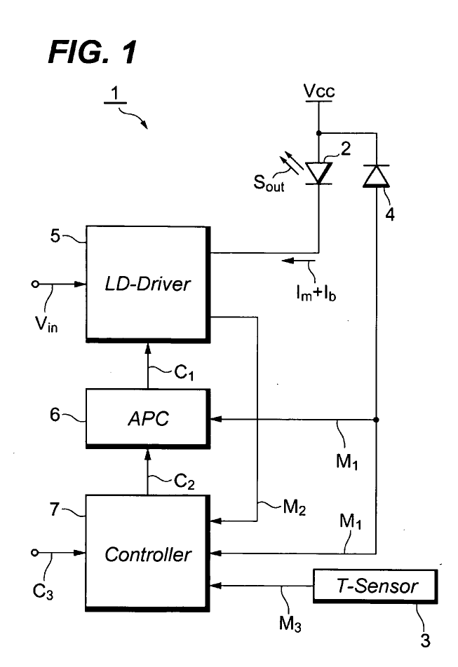

FIG. 1 is a block diagram of the optical transmitter according to the embodiment of the invention. The optical transmitter 1 converts an electric signal Vin into a corresponding optical signal Sout, and transmits this optical signal Sout into an optical transmission line, typically an optical fiber. The optical transmitter 1 includes an LD 2, a temperature sensor 3 disposed immediate to the LD 2, a PD for monitoring the optical output of the LD 2, an LD driver 5, an APC unit 6, and a controller 7.

The LD 2, whose anode is supplied a bias Vcc from the power supply, is connected in a cathode thereof with the LD driver 5. The LD driver generates the driving current that is a sum of a modulation current and a bias current. The modulation current Im corresponds to the input signal Vin and determine the extinction ratio of the optical output from the LD, while, the bias current Ib offsets the modulation currents Im. Typical configuration of the LD driver 5, although it is not appeared in FIG. 1, includes a differential circuit whose paired transistors are complementarily driven by the input signal Vin and a current source deciding a magnitude of the modulation current Im. The LD 2 thus supplied with the driving current emits light Sout with the average power determined by two currents, Im and Ib, and the extinction ration depending on the modulation current Im. The APC unit 6 outputs a command signal C1 to the LD driver 5 so as to maintain the average power and the extinction ration. The LD driver also provides a function to monitor the bias current Ib, and sends a monitoring signal M2 corresponding to the monitored result of the current Ib to the controller 7.

The optical transmitter further provides the PD 4 to monitor the optical output Sout from the LD 2 and to complete the APC feedback loop. The monitored signal M1 corresponding to the optical output Sout and detected by the PD 4 is output to the APC unit 6 and the controller 7. The APC unit 6, as explained above, outputs a command C1 to adjust the driving current Im+Ib based on the monitoring signal M1 so as to maintain the average power the extinction ratio.

The APC unit 6 provides a function to generate a command C1, when the command C2 output from the controller 7 becomes active, which is called as the command C2 is asserted, to stop the operation of the LD driver 5. That is, the LD driver 5 stops the provision of the driving current, Im+Ib, to the LD 2 to make the optical output from the LD 2 in shutdown. Moreover, the APC unit 6 commands the LD driver 5 to resume the provision of the driving current to the LD 2.

The controller 7, which includes a central processing unit often called as CPU, a memory and a peripheral interface to input/output the data, controls the APC loop to stop and to resume the optical output Sout based on the monitoring signals, M1 to M3. That is, the controller 7 receives the signal M1 from the PD 4, which corresponds to the current status of the optical output Sout, the signal M2 from the LD driver 5, which denotes the current status of the bias current Ib, and the signal M3 from the temperature sensor 3, which includes the current temperature of the LD 2.

Specifically, the controller 7 decides that the APC loop falls in the abnormal state when the monitored signal M2 exceeds a preset level A2, and discriminates the type of the abnormal state. As mentioned previously, two modes of the abnormal state are considered, one of which is (a) at least a failure of the device contained within the APC loop, which results in state that an excess driving current is to be supplied to the LD 2, and the other of which is (b) the thermal runaway of the LD 2 due to the increase of the ambient or the operating temperature of the LD 2. In the former abnormal mode (a), the monitored signal M1 from the PD 2 becomes substantially zero.

The controller 7 decides that the first abnormal state (a) occurs when the monitored signal M1 is less than the threshold A1, and asserts the command C2, which results in the shutdown of the LD 2. While, when the monitored signal M1 exceeds the threshold A1, the controller judges that the abnormal state is in the second mode (b), that is, the increase of the driving current is due to the thermal runaway of the LD 2. In this case, the controller 7 not only asserts the command C2 to make the optical output from the LD 2 in shutdown but also to start the monitoring of the ambient temperature of the LD 2. When the monitored signal M3 from the temperature sensor 3 becomes less than the third preset threshold A3, which corresponds to a threshold temperature, the controller decides that the thermal runaway of the LD 2 may be cancelled and negates the command C2 so as to resume the optical output from the LD 2. The controller 7 also provides a function to negate the command C2 responding to an external command C3.

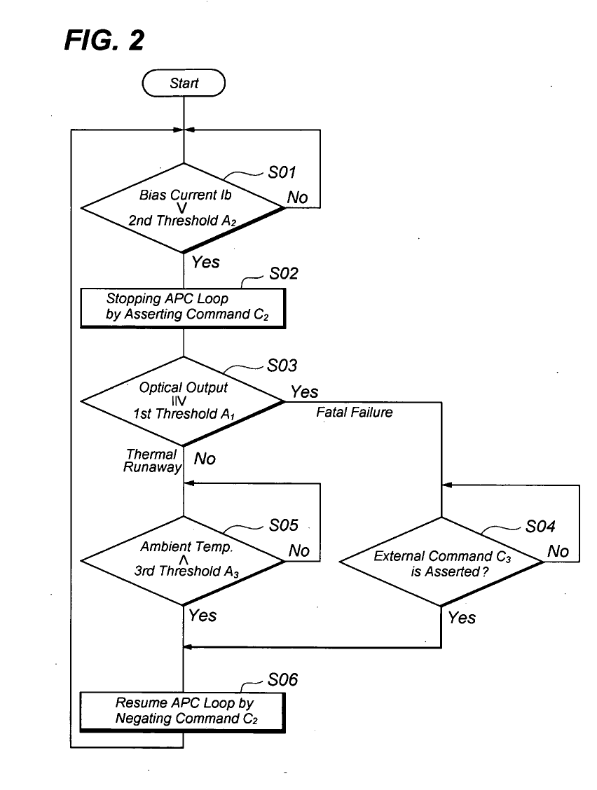

Next, a process flow to stop the optical output from the LD 2 will be described as referring to FIG. 2.

During the normal operation of the LD 2 according to the APC loop, the controller continues to monitor the bias current Ib and to compare the signal M2 corresponding to the bias current Ib with the threshold A2, step S01. When the signal M2 exceeds the threshold A2, which is denoted as “YES” in step S01 in FIG. 2 and corresponds to a state when the APC loop falls in the abnormal state, the controller compares the signal M1 corresponding to the optical output status with the first threshold A1 to decide the mode of the abnormal state in step S02.

When the signal M1 is less than the first threshold A1 that corresponds to a case “YES” in step S02 and means that the APC loop falls in the first abnormal state, the controller 7 asserts the command C2 to make the LD 2 in shutdown, step S03. After recovering the failure of the device in the APC loop, the controller 7 negates the command C2 by responding the external command C3, step S04, to resume the optical output Sout from the LD 2, and the procedure returns the original step S01.

While, the monitored signal M1 from the PD 4 exceeds the first threshold A1, which corresponds to “NO” in step S02, the controller 7 not only asserts the command C2 to stop the provision of the driving current to the LD 2, step S05, but the controller 6 begins to monitor the ambient temperature of the LD 2 in step S06. After subsequent monitoring of the ambient temperature; the controller negates the command C2 at step S07 when the monitored temperature is less than the third threshold A3. Thus, the optical output Sout from the LD 2 resumes the original state and the process to control the LD 2 returns step S01.

According to the optical transmitter 1, the controller 7 always monitors the bias current Ib and, when the bias current exceeds the threshold, the controller 7 stops the APC unit 6 so as to make the optical output in shutdown. When the signal from the PD, which corresponds to the optical output Sout immediately before the shutdown, exceeds the first threshold A1, the controller decides that the abnormal increase of the bias current is due to the thermal runaway of the LD 2 and continuously monitors the ambient temperature of the LD 2. The controller 7 further decides that, when the monitored signal from the temperature sensor becomes less than the third threshold, the thermal runaway becomes clear and negates the command C2 to the APC unit 6 so as to resume the APC loop to supply the appropriate driving current to the LD 2.

Thus, the optical transmitter according to the present invention may distinguish two types of the abnormal states of the APC loop detected by the monitoring of the bias current supplied to the LD, one of which is due to the thermal runaway of the LD and the other of which is due to the fatal failure of the device in the APC loop. Therefore, the optical transmitter of the invention may automatically resume the APC operation in an appropriate timing when the abnormal in the APC loop is due to the thermal runaway of the device.

A few preferred embodiments have been described in detail hereinabove. It is to be understood that the scope of the invention also comprehends embodiments different from those described, yet within the scope of the claims. Words of inclusion are to be interpreted as non-exhaustive in considering the scope of the invention.

I claim:

1. An optical transmitter, comprising:
an automatic power control loop including a semiconductor laser diode, a laser driver to supply a driving current to said laser diode, a photodiode to monitor an optical output from said laser diode, and an APC unit to control said laser driver depending on said optical output from said laser diode so as to keep an extinction ratio and an average power of said optical output;
a temperature sensor to sense an ambient temperature of said laser diode; and
a controller to monitor said driving current, said optical output and said ambient temperature,
wherein said controller stops said APC loop when said driving current exceeds a first threshold and resume said APC loop when said optical output immediately before said stop of said APC loop exceeds a second threshold and said ambient temperature becomes less than a third threshold.

2. The optical transmitter according to claim 1,
wherein said controller resume said APC loop responding to an external command provided from an outside of said optical transmitter when said optical output immediately before said stop of said APC loop is less than said second threshold.

3. A method to control an optical transmitter including an APC loop comprised of a laser diode to emit an optical output, a laser driver to supply a driving current to said laser diode, a photodiode to monitor said optical output and an APC unit to control said laser driver based on said optical output, said method comprising steps of:
stopping said APC loop when said driving current exceeds a first threshold; and
when said optical output power immediate before said stop of said APC loop exceeds a second threshold, resuming said APC loop responding to an ambient temperature of said laser diode exceeding a third threshold.

4. The method according to claim 3,
further comprising a step of resuming said APC loop responding to an external command provided from an outside of said optical transmitter when said optical output immediate before said stop of said APC loop is less than a second threshold.
